(19) United States
(12) Patent Application Publication
(10) Pub. No.: US 2026/0090046 A1
(43) Pub. Date: Mar. 26, 2026

(54) Power Semiconductor Device and Method of Producing a Power Semiconductor Device

(71) Applicant: Infineon Technologies Austria AG, Villach (AT)

(72) Inventors: Murugalogeswaran Permal, Sungkai (MY); Anton Mauder, Kolbermoor (DE)

(21) Appl. No.: 19/324,304

(22) Filed: Sep. 10, 2025

(30) Foreign Application Priority Data
Sep. 25, 2024 (DE) 102024209265.7

(51) Int. Cl. H10D 62/60; H01L 21/033; H01L 21/266; H01L 23/29; H01L 23/31; H10D 12/00

(52) U.S. Cl. CPC H10D 62/60; H10D 12/415; H10P 30/22; H10P 76/4085; H10W 74/137; H10W 74/43; H10W 74/47; H10W 74/481

(57) ABSTRACT

A method of producing a power semiconductor device includes: providing a semiconductor body with a front side having a substantially horizontal area above both an active region and an edge termination region of the semiconductor body; forming, at the front side, a first insulation layer above both the active region and the edge termination region; forming, at the first insulation layer, a first mask layer that covers the edge termination region at least partially and exposes the active region; removing a portion of the first insulation layer covering the active region; and while the first mask layer or a modified first mask layer or another mask layer covers the edge termination region, subjecting the edge termination region to a first implantation processing step to form, in the edge termination region, one or more doped semiconductor regions.

### TECHNICAL FIELD

This specification refers to embodiments of a power semiconductor device and to embodiments of a method of producing a power semiconductor device. Some embodiments presented herein relate to the integration of a high voltage termination structure with silicon oxide and a Variable Lateral Doping, VLD, region.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

High voltage devices may hence require a definition of the active region and edge termination region, which may further need to be aligned with each other. In some implementations, an edge termination exhibiting a VLD (variation of lateral doping) configuration is chosen due to a reliability reasons. In the area of the edge termination region, the surface of the semiconductor body may also have a termination structure, e.g., based on thermal oxidation, e.g., due to a low density of interface charges and traps.

The present specification proposes techniques related to a low-cost manufacturing method of an edge termination region of a power semiconductor device.

### SUMMARY

According to an embodiment, a method of producing a power semiconductor device comprises: providing a semiconductor body, wherein the semiconductor body has a front side having a substantially horizontal area above both an active region and an edge termination region of the semiconductor body; forming, at the front side, a first insulation layer above both the active region and the edge termination region; forming, at the first insulation layer, a first mask layer, wherein the first mask layer covers the edge termination region at least partially and exposes the active region; and removing a portion of the first insulation layer covering the active region; while the first mask layer or a modified first mask layer or another mask layer covers the edge termination region, subjecting the edge termination region to a first implantation processing step to form, in the edge termination region, one or more doped semiconductor regions.

According to another embodiment, a power semiconductor device is presented, wherein the power semiconductor device has been produced in accordance with the method described in the preceding paragraph.

According to a further embodiment, a power semiconductor device comprises: a semiconductor body, wherein the semiconductor body has a front side having a substantially horizontal area above both an active region and an edge termination region of the semiconductor body; a first insulation layer above the edge termination region, wherein the first insulation layer is a thermally grown oxide in contact with the front side and having a thickness within the range of 50 nm to 500 nm; and below the front side in the edge termination region, a Variation-of-Lateral-Doping, VLD, region.

According to a yet further embodiment, a power semiconductor device comprises: a semiconductor body, wherein the semiconductor body has a front side having a substantially horizontal area above both an active region and an edge termination region of the semiconductor body; a first insulation layer above the edge termination region and in contact with the front side; and below the front side in the edge termination region, a doped semiconductor region, wherein the doped semiconductor region exhibits, along a vertical direction, a dopant concentration profile, according to which: the dopant concentration at the front side has a start value N_{A_0}; the dopant concentration reaches a maximal value N_{A_MAX} greater than the start value N_{A_0} at a first vertical distance Z_{MAX} from the front side; the dopant concentration continuously decreases along the vertical direction after the first vertical distance Z_{MAX} and re-reaching the start value N_{A_0} at a second vertical distance Z_{MED} from the front side; and (N_{A_MAX}−NA_0)/N_{A_MAX} is not larger than ⅓.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1-3 schematically and exemplarily illustrate, based on sections of vertical cross-sections of a power semiconductor device being produced, a method of producing the power semiconductor device in accordance with some embodiments;

FIG. 4 schematically and exemplarily illustrates a dopant concentration profile in a power semiconductor device in accordance with one or more embodiments; and

FIG. 5 schematically and exemplarily illustrates a section of a vertical cross-section of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z”herein.

The first conductivity type is opposite to the second conductivity type. In this specification, n-doped is referred to as “first conductivity type” while p-doped is referred to as “second conductivity type”. Alternatively, opposite doping relations can be employed so that the first conductivity type can be p-doped and the second conductivity type can be n-doped. A dopant dose may be defined as the integral over the dopant concentration of the atoms of the respective conductivity type within a respective doping region in a vertical direction Z. The dopant dose may be the amount of dopant implanted per area.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective power semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “forward conducting state” of the power semiconductor device while a forward voltage bias is applied. A transition between the forward blocking state and the forward conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the forward blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the range of several A, e.g., up to several ten or hundred Ampere, and/or high voltages, typically above 100 V, more typically 300 V and above, e.g., up to at least 600 V or even more, e.g., up to at least 1.2 kV, or even up to 6 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip and can be configured to be employed as a power component in a low-, medium-, and/or high voltage application.

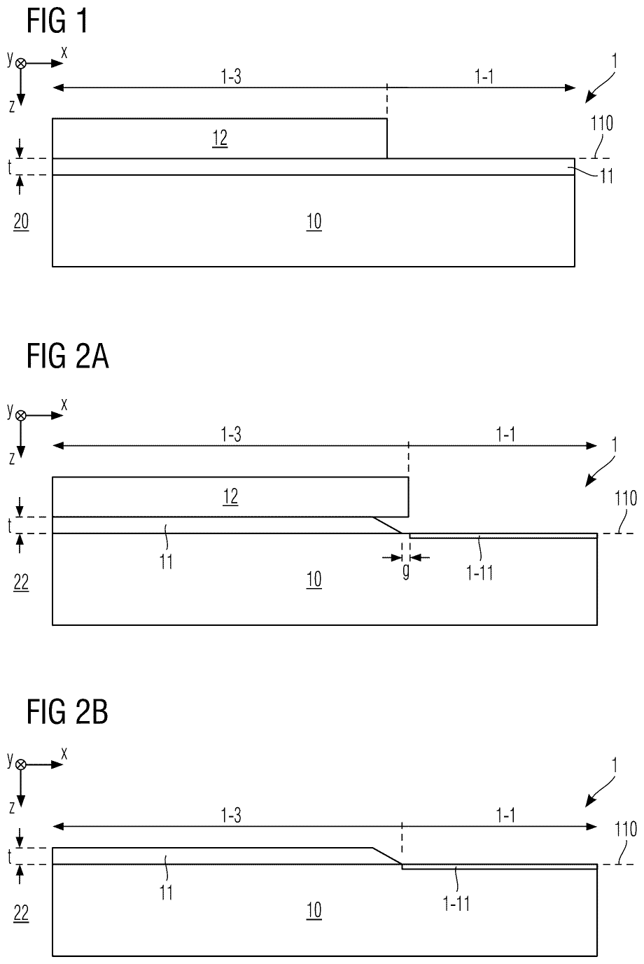

FIGS. 1 to 3 schematically and exemplarily illustrate, based on sections of vertical cross-sections of a power semiconductor device being produced, a method of producing the power semiconductor device 1 in accordance with some embodiments.

The method comprises providing, in stage 20 (cf. FIG. 1), a semiconductor body 10. For example, the semiconductor body 10 is based on silicon, Si.

The semiconductor body 10 has a front side 110 having a substantially horizontal area above both an active region 1-1 and an edge termination region 1-3 of the semiconductor body 10, as illustrated in FIG. 1.

The method further comprises forming, in stage 20 (cf. FIG. 1), at the front side 110, a first insulation layer 11 above both the active region 1-1 and the edge termination region 1-3. For example, the first insulation layer 11 is based on an oxide. The first insulation layer 11 may be formed by carrying out an oxidation processing step and/or deposition processing step.

The method further comprises forming, in stage 20 (cf. FIG. 1), at the first insulation layer 11, a first mask layer 12. The first mask layer 12 covers the edge termination region 1-3 at least partially and exposes the active region 1-1, e.g., at least partially or entirely. For example, the first mask layer 12 defines the lateral transition between the edge termination region 1-3 and the active region 1-2.

The method further comprises forming, in stage 22 (cf. FIG. 2A), removing a portion of the first insulation layer 11 covering the active region (1-1). In an embodiment, during stage 22 (cf. FIG. 2B), also the first mask layer 12 is removed and/or modified and/or replaced with another mask layer 13.

The method further comprises forming, in stage 24 (cf. FIG. 3), after the first mask layer 12 or a modified first mask layer 12 or another mask layer 13 is opened above the edge termination region 1-3, at least partially subjecting the edge termination region 1-3 to a first implantation processing step (indicated by the bold arrow marked with a “I²”) to form, in the edge termination region 1-3, one or more doped semiconductor regions 1-31.

For example, the first implantation processing step is carried out with an implantation energy of less than 500 keV, of less than 200 keV or of even less than 100 keV. The actual implantation energy may be chosen in dependence of the thickness t of the first insulation layer 11.

For example, the first implantation processing step is carried out to form, below the front side 110 and in the edge termination region 1-3, a Variation-of-Lateral-Doping, VLD, region 1-31. For example, the method comprises modifying the first mask layer 12 to obtain a modified first mask layer 12 by forming a plurality of openings 1213 in the first mask layer 12, wherein the openings 1213 correspond to an intended Variation-of-Lateral-Doping, VLD, region 1-31. Then, the Variation-of-Lateral-Doping, VLD, region 1-31 can be formed during the first implantation processing step. Of course, instead of modifying the first mask layer 12, mask layer 12 could also be replaced by another layer 13 exhibiting said openings 1213 corresponding to the intended Variation-of-Lateral-Doping, VLD, region 1-31. After the first implantation processing step, a diffusion processing step may be carried out to achieve a contiguous VLD-region 1-31.

After a diffusion processing, the VLD-region 1-31 may exhibit a continuous function, e.g. a linear gradient, of the doping concentration in the semiconductor body 10 starting at the interface to the active region 1-1 with the highest value. On the way towards the outer edge of the edge termination region 1-2, said doping concentration is dropping and may finally lead to substantially no increased doping concentration compared to a background doping of the semiconductor body 10. While, at the interface to the active region 1-1, the doping concentration of the VLD-region 1-31 is high enough to be not fully depleted by the space charge region in static blocking operation, at the outer parts of the VLD-region 1-31, the space charge region in static blocking operation will reach the interface of semiconductor body 10 and first insulation layer 11. On the way from the from the active region 1-1 to the outer edge termination, the doping of the VLD-region 1-31 may have one or more regions of constant concentration (e.g. at the interface to the active region 1-1) and one or more steep steps of the doping concentration, e.g. at the outer edge of the VLD-region 1-31. Since the diffusion processing step may not be sufficient to fully distribute implanted doping atoms, a moving average of the doping concentration may be formed with a lateral width of the averaging length of e.g. 3 times or 5 times the depth of the VLD-region 1-31 in the semiconductor body 10 leading to average values of said dopant concentration within the VLD-region 1-31 as described above.

In an embodiment, the VLD-region 1-31 may exhibit a Junction-Termination-Extension, JTE, configuration. While the VLD-region 1-31 shows a gradient in the doping concentration, at the JTE edge termination, the doping concentration may drop in steps and will be substantially constant in one step. Also, at the JTE edge termination may start with a doping concentration that is too high to be fully depleted by the space charge region and having one or more additional steps in doping concentration which have a fully depletable doping concentration.

Still referring to stage 24 as illustrated in FIG. 3, the method may further comprise forming, before the first implantation processing step is carried out, a further mask layer 14 to cover the active region 1-1 at least partially. Thereby, it may be ensured that the active region 1-1 is not subjected to the first implantation processing step. In another embodiment, also the active region 1-1 may be subjected to the first implantation processing step, e.g., while being covered with a structured mask.

For example, referring to stage 20 as exemplarily illustrated in FIG. 1, the first insulation layer 11 includes or consists in a thermally grown oxide. For example, formation of the first insulation layer 11 does not include a deposition processing step. For example, the semiconductor body 10 is based on silicon, Si, and the first insulation layer 11 is thermally grown silicon oxide, SiO₂. During thermal growth of SiO₂, some of the originally available semiconductor material of the semiconductor body 10 is consumed leading to a step at the front side 110 of the semiconductor body 10. Therefore, the insulation layer 11 may be partially buried below the original extension of the front side 110.

For example, referring to stage 20 as exemplarily illustrated in FIG. 1, before forming 20, at the first insulation layer 11, the first mask layer 12, a thickness t of the first insulation layer 11 is within the range of 50 nm to 500 nm. Further, in an embodiment, the thickness t of the first insulation layer 11 is substantially constant within the total horizontal extension (along the first and second lateral directions X and Y) of the first insulation layer 11.

Furthermore, in an embodiment, the first insulation layer 11 is present while carrying out the step of subjecting (cf. stage 24 in FIG. 3) the edge termination region 1-3 to said first implantation processing step. The first insulation layer 11 can be configured to mask doping ions being implanted with an implantation energy of 10 keV or less.

In an embodiment, the first insulation layer 11 may be arranged so as to adjoin the front side 110 of the semiconductor body 10 or, respectively, does not penetrate the semiconductor body 10. For example, the first insulation layer 11 may be arranged so as to not extend further along the vertical direction Z as the front side 110 formed by the portion of semiconductor body 10 in the active region 1-1. Of course, said optional provisions take into account that the first insulation layer 11 may be based on a thermal growth processing step according to which the front side 110 of the original semiconductor body 10 is subjected to an oxidation processing step.

Referring to FIGS. 2A and 2B, the method may in an embodiment further comprise, after removing (cf. stage 22) said portion of the first insulation layer 11 covering the active region 1-1, subjecting (cf. stage 22) the active region (1-1) to a second implantation processing step (indicated by the bold arrows marked with a “I²”) to form, in the active region 1-1, one or more doped semiconductor regions 1-11.

The second implantation processing step may be carried out after the first implantation processing step, or the second implantation processing step is carried out before the first implantation processing step.

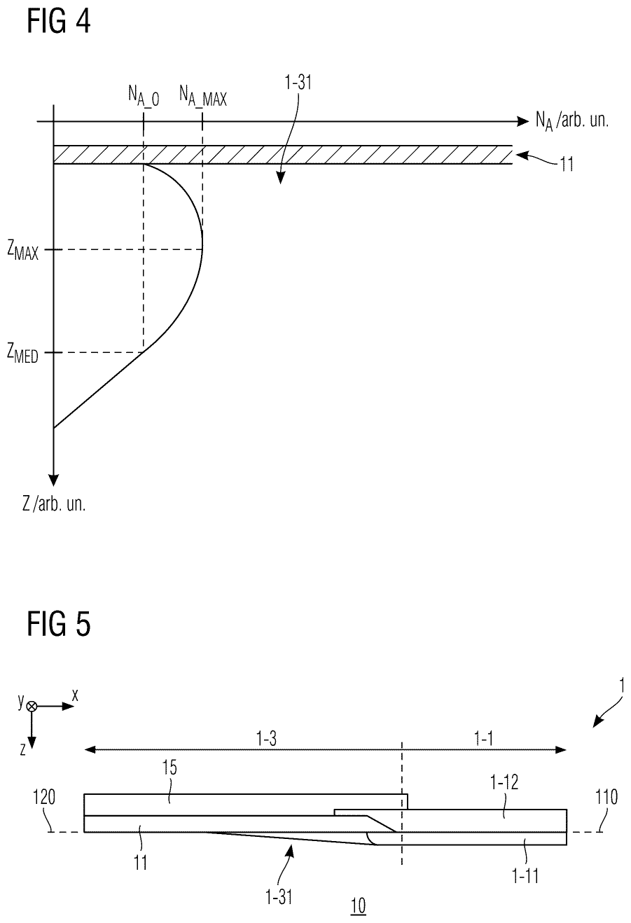

Depending on how the first insulation layer removal step is carried out and/or on how the first mask layer 12 is modified, removed or replaced, a small gap g may remain between the one or more doped semiconductor regions 1-11 and the first insulation layer 11 (cf. FIG. 2A) or a small lateral overlap is formed between the one or more doped semiconductor regions 1-11 and the first insulation layer 11 (cf. FIG. 2B). In any case, it may be ensured that the one or more doped semiconductor regions 1-11 at least adjoin after a diffusion step or overlap the VLD-region 1-31, as illustrated in FIGS. 3 and 5.

After diffusion, a blocking pn junction in the active area 1-1 has to be in a conductive connection with the VLD-region 1-31. In case of only little over-etch of the first insulation layer 11 and strong diffusion, the final result of FIGS. 2A and 2B may be only little and not discriminable. With a large over-etch of the insulation layer 11 and process according to FIG. 2A, the lateral end of the doping region 1-11 in FIG. 5 may end before the full thickness of the insulation layer 11 is reached.

Before the device is further processed, e.g., by being equipped with an encapsulation or the like, the (modified) first mask layer 12 or, respectively, the other mask layer 13 covering the edge termination region 1-3 may be removed. Also, the second mask layer 14 may be removed.

For example, cf. FIG. 5, after mask removal, a passivation layer 15 above the first insulation layer 11 in the edge termination region 1-3 may be formed. For example, the passivation layer 15 comprises at least one of an inorganic isolation material, a silicon nitride, a silicon oxide, an electro-active material, a semi-insulating polycrystalline silicon, a diamond-like carbon, DLC, Si-rich Si₃N₄, an organic isolation material, an imide or a silicone.

Still referring to FIG. 5, in an embodiment, the method may further comprise forming a metal layer 1-12 at the semiconductor body 10. For example, the metal layer 1-12 is in direct physical contact with the semiconductor body 10 (e.g., partly or everywhere) where the portion of the first insulation layer 11 covering the active region (1-1) was previously removed (cf. transition from stage 20 to stage 22 illustrated in FIGS. 1, 2A and 2B). For example, the metal layer 1-12 forms a part of a first load terminal of the power semiconductor device 1. For example. the metal layer 1-12 is in direct physical contact with a remaining portion of the first insulation layer 11, e.g., the remaining portion of the first insulation layer 11 which is not removed during the removing stage 22. An overlapping portion of metal layer 1-12 may extend above the first insulation layer 11. Generally, the forming of the metal layer 1-12 may be done after the removing stage 22 and after the subjecting in stage 24.

Presented herein is also a power semiconductor device 1, wherein the power semiconductor device 1 has been produced in accordance with a method of one of the precedingly described embodiments.

For example, the power semiconductor device comprises semiconductor body 10, wherein the semiconductor body has a front side having a substantially horizontal area above both an active region and an edge termination region of the semiconductor body; a first insulation layer above the edge termination region, wherein the first insulation layer is a thermally grown oxide in contact with the front side and having a thickness within the range of 50 nm to 500 nm; and below the front side in the edge termination region, a Variation-of-Lateral-Doping, VLD, region. Embodiments of this power semiconductor device correspond to the embodiments of the method described above. Thus, regarding the embodiments of the power semiconductor device, it is referred to the above.

In accordance with a further embodiment, a power semiconductor device comprises a semiconductor body, wherein the semiconductor body has a front side having a substantially horizontal area above both an active region and an edge termination region of the semiconductor body; a first insulation layer above the edge termination region and in contact with the front side; and below the front side in the edge termination region, a doped semiconductor region, wherein the doped semiconductor region exhibits, along a vertical direction, a dopant concentration profile, according to which: the dopant concentration at the front side has a start value N_{A_0}; the dopant concentration reaches a maximal value N_{A_MAX} greater than the start value N_{A_0} at a first vertical distance Z_{MAX} from the front side; the dopant concentration continuously decreases along the vertical direction after the first vertical distance Z_{MAX} and re-reaching the start value N_{A_0} at a second vertical distance Z_{MED} from the front side; and (N_{A_MAX}−NA_0)/N_{A_MAX} is not larger than ⅓.

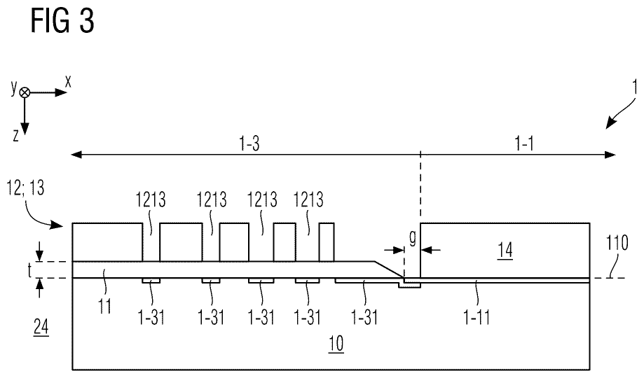

Regarding the above-described embodiments of the power semiconductor device 1, reference is made to FIG. 4, which schematically and exemplarily illustrates a dopant concentration profile in the power semiconductor device 1 in accordance with one or more embodiments. The horizontal axis shows the magnitude of the dopant concentration N_{A} (in an arbitrary unit, e.g., 1/cm³) in the VLD-region 1-31, and the vertical axis shows the level along the vertical direction Z (in an arbitrary unit, e.g., μm).

Accordingly, in an embodiment, below the first insulation layer 11, the dopant concentration at the front side 110 has the start value N_{A_0}. Along the vertical direction Z, the dopant concentration reaches the maximal value N_{A_MAX} (which is greater than the start value N_{A_0}) at the first vertical distance Z_{MAX} from the front side 110. The dopant concentration then continuously decreases along the vertical direction Z after the first vertical distance Z_{MAX} and re-reaching the start value N_{A_0} at the second vertical distance Z_{MED} from the front side 110.

In an embodiment, the dopant concentration profile exhibits a further maximal value, wherein the further maximal value can be greater or smaller than the maximal value N_{A_MAX}.

For example, the above-described embodiments of the power semiconductor device may exhibit a MOSFET configuration, an IGBT configuration or a configuration derived from a MOSFET configuration or an IGBT configuration.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixCl-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A method of producing a power semiconductor device, the method comprising:
providing a semiconductor body, wherein the semiconductor body has a front side having a substantially horizontal area above both an active region and an edge termination region of the semiconductor body;
forming, at the front side, a first insulation layer above both the active region and the edge termination region;
forming, at the first insulation layer, a first mask layer that covers the edge termination region at least partially and exposes the active region;
removing a portion of the first insulation layer covering the active region; and
while the first mask layer or a modified first mask layer or another mask layer covers the edge termination region, subjecting the edge termination region to a first implantation processing step to form, in the edge termination region, one or more doped semiconductor regions.

2. The method of claim 1, wherein the first insulation layer comprises a thermally grown oxide.

3. The method of claim 1, wherein, before forming the first mask layer at the first insulation layer, a thickness of the first insulation layer is within a range of 50 nm to 500 nm.

4. The method of claim 3, wherein the thickness of the first insulation layer is substantially constant within the total horizontal extension of the first insulation layer.

5. The method of claim 3, wherein the thickness of the first insulation layer is present while the edge termination region is subjected to the first implantation processing step.

6. The method of claim 1, wherein the first insulation layer is configured to mask doping ions being implanted with an implantation energy of less than 10 keV.

7. The method of claim 1, wherein the first insulation layer adjoins the front side of the semiconductor body or, respectively, does not penetrate the semiconductor body.

8. The method of claim 1, wherein the semiconductor body is based on silicon, and wherein the first insulation layer is a thermally grown silicon oxide.

9. The method of claim 1, further comprising:
after removing the portion of the first insulation layer covering the active region, subjecting the active region to a second implantation processing step to form, in the active region, one or more doped semiconductor regions.

10. The method of claim 1, wherein the first implantation processing step is carried out with an implantation energy of less than 500 keV.

11. The method of claim 1, wherein the first implantation processing step is carried out to form, below the front side in the edge termination region, a variation-of-lateral-doping (VLD) region.

12. The method of claim 11, further comprising:
modifying the first mask layer to obtain a modified first mask layer, by forming a plurality of openings in the first mask layer corresponding to the VLD region; and
forming the VLD region during the first implantation processing step.

13. The method of claim 1, further comprising:
before the first implantation processing step is carried out, forming a further mask layer to cover the active region at least partially.

14. The method of claim 1, further comprising:
removing the first mask layer or the modified first mask layer.

15. The method of claim 1, wherein the first mask layer defines a lateral transition between the edge termination region and the active region.

16. The method of claim 1, further comprising:
forming a passivation layer above the first insulation layer in the edge termination region.

17. The method of claim 16, wherein the passivation layer comprises at least one of an inorganic isolation material, a silicon nitride, a silicon oxide, an electro-active material, a semi-insulating polycrystalline silicon, a diamond-like carbon, DLC, Si-rich Si₃N₄, an organic isolation material, an imide, and a silicone.

18. The method of claim 1, further comprising:
forming a metal layer in direct physical contact with the semiconductor body where the portion of the first insulation layer covering the active region was previously removed.

19. The method of claim 18, wherein the metal layer is in direct physical contact with a remaining portion of the first insulation layer.

20. A power semiconductor device, comprising:
a semiconductor body, wherein the semiconductor body has a front side having a substantially horizontal area above both an active region and an edge termination region of the semiconductor body;
a first insulation layer above the edge termination region, wherein the first insulation layer is a thermally grown oxide in contact with the front side and having a thickness within a range of 50 nm to 500 nm; and
below the front side in the edge termination region, a variation-of-lateral-doping (VLD) region.

21. The power semiconductor device of claim 20, wherein the power semiconductor device is one of a diode, a MOSFET or an IGBT, or a derivate thereof.

22. A power semiconductor device, comprising:
a semiconductor body, wherein the semiconductor body has a front side having a substantially horizontal area above both an active region and an edge termination region of the semiconductor body;
a first insulation layer above the edge termination region and in contact with the front side; and
below the front side in the edge termination region, a doped semiconductor region, wherein the doped semiconductor region exhibits, along a vertical direction, a dopant concentration profile, according to which:
the dopant concentration at the front side has a start value (N_{A_0});
the dopant concentration reaches a maximal value (N_{A_MAX}) greater than the start value at a first vertical distance (Z_{MAX}) from the front side;
the dopant concentration continuously decreases along the vertical direction after the first vertical distance and then reaches the start value again at a second vertical distance from the front side; and
(N_{A_MAX}−NA_0)/N_{A_MAX} is not larger than ⅓.

23. The power semiconductor device of claim 22, wherein the power semiconductor device is one of a diode, a MOSFET or an IGBT, or a derivate thereof.
